(19) United States
(12) Patent Application Publication
(10) Pub. No.: US 2007/0125639 A1
(43) Pub. Date: Jun. 7, 2007

(54) Method and apparatus for producing a protective layer

(75) Inventors: Thomas Cosack, Windach (DE); Wolfgang Eichmann, Puchheim (DE)

Correspondence Address: CROWELL & MORING LLP;INTELLECTUAL PROPERTY GROUP, P.O. BOX 14300, WASHINGTON, DC, 20044-4300, US

(73) Assignee: MTU Aero Engines GmbH, Munich (DE)

(21) Appl. No.: 10/580,442

(22) PCT Filed: Nov. 4, 2004
(86) PCT No.: PCT/DE04/02437

§ 371 Date: Feb. 8, 2007

(30) Foreign Application Priority Data
Nov. 25, 2003 (DE) 103 55 036.4

(51) Int. Cl. C23C 14/32

(52) U.S. Cl. 204/192.16

(57) ABSTRACT

A method and apparatus for producing a protective layer to prevent oxidation and/or corrosion for components, in particular for components of a gas turbine, are disclosed. In the method a component having a substrate surface and a substrate composition are provided. Then a coating material is supplied, where the coating material contains at least platinum and aluminum. Then the coating material consisting of at least platinum and aluminum is deposited on the component to be coated in a PVD process (Physical Vapor Deposition Process). Platinum and aluminum are deposited jointly with a single PVD process on the component to be coated.

### BACKGROUND AND SUMMARY OF THE INVENTION

This application claims the priority of International Application No. PCT/DE2004/002437, filed Nov. 4, 2004, and German Patent Document No. 103 55 036.4, filed Nov. 25, 2003, the disclosures of which are expressly incorporated by reference herein.

The invention relates to a method for producing a protective layer, namely an oxidation and/or corrosion preventing layer, for components, especially for components of a gas turbine. In addition, the invention relates to a protective layer and a component having such a protective layer.

Coatings of at least platinum and aluminum that act as oxidation and/or corrosion preventing layers for gas turbine components have long been known from the state of the art. To produce such protective coatings, it is already known from the state of the art that platinum can be applied to a component that is to be coated by the electroplating method and then aluminum is applied separately in a separate operation. According to the state of the art, aluminum plating of a component that has already been plated with platinum is preferably performed by diffusion. Thus according to the state of the art, coating a component with platinum and aluminum is performed in two separate operations. First, the component is coated with platinum, preferably by electroplating, and then it is coated with aluminum, preferably by diffusion. Separate application of platinum and aluminum is a disadvantage from the standpoint of the process engineering because the time to produce the corresponding protective layer is prolonged due to the separate coating processes that must be performed in succession.

Against this background, the object of the present invention is to create a novel method for producing a protective coating, a novel protective coating and a component having such a protective coating.

According to this invention, in a first step of the method, a component is supplied with a substrate surface and a substrate composition. In a second step, a coating material is prepared, whereby the coating material consists of at least platinum (Pt) and aluminum (Al). Then the coating material, consisting at least of platinum (Pt) and aluminum (Al), is deposited on the component to be coated by PVD process (Physical Vapor Deposition Process). The platinum (Pt) and the aluminum (Al) are deposited jointly in a single PVD process on the component to be coated.

In the sense of the present invention, it is provided for the first time that platinum and aluminum be applied jointly with the help of a PVD process in a single process step. In this way, the separate aluminization required in the state of the art may be omitted. With the help of this invention, protective layers having the required protective properties can be produced more rapidly than according to the state of the art.

According to an advantageous refinement of the present invention, cathode sputtering is used as the PVD process, whereby the sputtering is preferably performed under a protective gas atmosphere.

Preferred refinements of the present invention are derived from the following description.

### BRIEF DESCRIPTION OF THE DRAWINGS

Exemplary embodiments of the invention are explained in greater detail below on the basis of the drawings without being limited to these embodiments. They show:

FIG. 1 is a component of a gas turbine; and

FIG. 2 is a schematic process arrangement to illustrate the inventive process for producing the inventive protective layer.

### DETAILED DESCRIPTION OF THE DRAWINGS

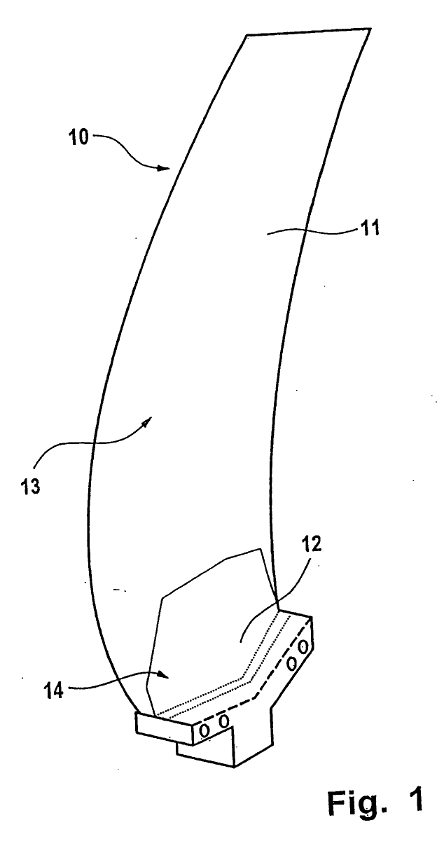

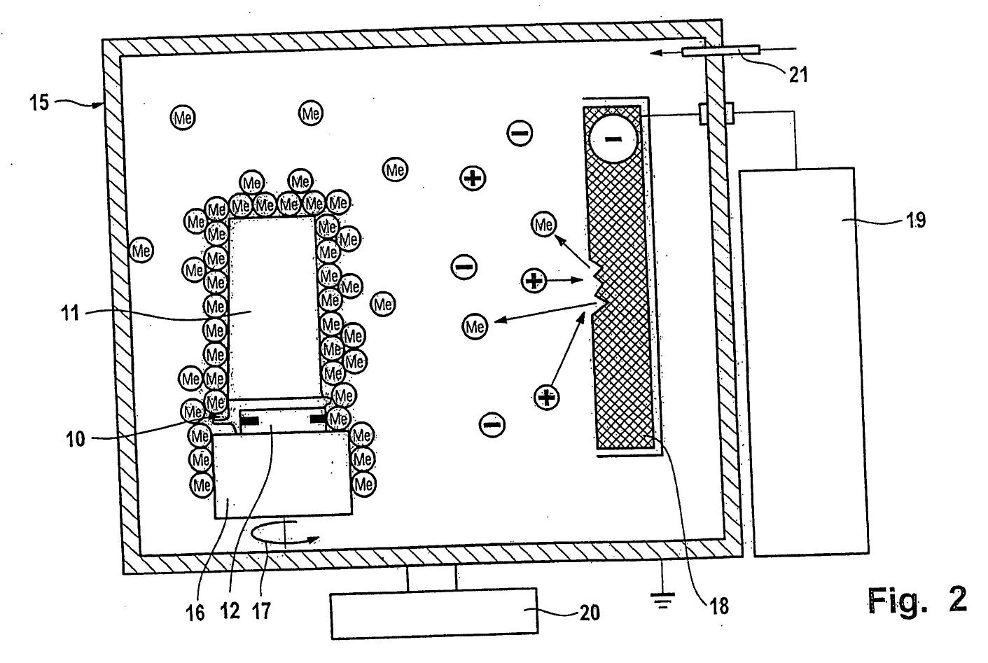

The present invention is explained in greater detail below with reference to FIGS. 1 and 2.

FIG. 1 shows a blade 10 of a gas turbine as the component to be coated. According to FIG. 1, the blade 10 has a blade pan 11 and a blade foot 12. The blade 10 is also referred to as the substrate to be coated and has a substrate composition. The substrate composition of the blade 10 may be based on a nickel-based alloy or on a cobalt-based alloy. It is also possible with the inventive method to coat components whose substrate composition is a titanium-based alloy.

The components to be coated, namely in the exemplary embodiment shown here, the blade 10 to be coated, is provided with an oxidation preventing layer and a corrosion preventing layer at its surface. According to FIG. 1, both a substrate surface 13 in the area of the blade pan 11 and a substrate surface 14 in the area of the blade foot 12 are to be provided with the protective layer. It is also conceivable to coat the blade 10 only in some areas by the inventive method, either in the area of the substrate surface 13 or in the area of the substrate surface 14.

In the sense of the present invention, the oxidation preventing layer and/or the corrosion preventing layer for the blade 10 of a gas turbine is produced by depositing a coating material containing at least platinum and aluminum onto the component to be coated by means of a PVD process. The details of the PVD process (PVD is an abbreviation for Physical Vapor Deposition) will be discussed below with reference to FIG. 2.

FIG. 2 shows a process chamber 15 which is designed as a vacuum chamber and in which the blade 10 that is to be coated is positioned on a holder 16. The blade 10 positioned on the holder 16 may be rotated inside the process chamber 15 in the direction of the arrow 17 to ensure uniform coating of the blade 10 on all sides.

In addition to the blade 10 to be coated, coating material 18 which is also referred to as the target, is arranged inside the process chamber 15. The coating material 18, i.e., the target, is connected to a voltage, i.e., power supply source 19, with the coating material 18 forming a cathode as illustrated in FIG. 2.

To coat the blades 10 arranged in the process chamber 15 with the coating material 18, which is also arranged in the process chamber 15, the process chamber 15 is evacuated with the help of a vacuum pump 20 and then process gas is introduced into the vacuum chamber 15 through the feed device 21. The process gas is preferably argon and/or krypton.

Inside the vacuum chamber 15, gas ions of the process gas are accelerated through the voltage field applied to the coating material 18 and are deposited on the coating material 18. In doing so, gas ions from the coating material 18 leverage metal atoms or metal molecules out of the coating material 18. The coating material 18 is thus atomized by transfer of momentum of the gas ions. The atomized atoms or molecules of the coating material are deposited on the blade 10 to be coated and on the holder 16 and thus form a coating on the blade 10. The PVD process described above in which the gas ions are thrown out of the coating material 18 which form the cathode by way of a mechanical process is also known as cathode atomization or sputtering.

Sputtering is special case of PVD coating and is preferred for the present invention.

In the present invention in which the blade 10 to be coated is coated with an oxidation preventing layer and/or a corrosion preventing layer consisting of aluminum and platinum, the coating material 18 contains at least platinum and aluminum. Thus the coating material 18 may be, for example, a sheet of high-purity aluminum into which are integrated islands, i.e., inserts, of high-purity platinum.

In addition to aluminum and platinum, the coating material 18 may also contain nickel and optionally cobalt. Nickel and cobalt, like platinum, may also be integrated as islands, i.e., inserts, into a sheet of high-purity aluminum. Furthermore, the coating material 18 may also contain yttrium, hafnium and silicon.

The composition of the coating material 18 is adapted first to the substrate composition of the blade 10 to be coated and secondly to the composition of the protective layer to be produced. The coating material 18 must at least supply aluminum and platinum in a sufficient amount and with an adjusted composition, so that after sputtering the result is a protective layer having the desired composition. One factor to be taken into account here is that the composition of the coating material 18, i.e., the target, is shifted in favor of the slower, i.e., more inert, i.e., less active, element. This means that in the case of a coating material made of platinum and aluminum, the ratio of platinum and aluminum in the coating material is shifted in favor of platinum in comparison with the desired composition of the protective layer, and the platinum behaves with greater inertia in coating in comparison with aluminum.

As explained above, the target, i.e., the coating material 18, is preferably a sheet of high-purity aluminum containing inserts, i.e., islands, of high-purity platinum and optionally high-purity nickel and high-purity cobalt integrated into it. In the sense of the present invention, it is also possible to supply a sheet element as the coating material 18 which is provided by hot isostatic pressing (HIP process) of at least aluminum powder, platinum powder and optionally nickel powder. In this case, the coating material 18 is formed by elements which are present in a so-called intermetallic phase. This makes it possible to produce protective coatings having an especially high oxidation resistance.

It is also within the sense of the present invention to subject the coated component, i.e., in the exemplary embodiment shown here the coated blade 10, to a heat treatment after coating by the PVD process. With the help of this heat treatment, the aluminum and platinum deposited at the surface of the blade 10 can be made to defuse into the surface of the blade 10.

According to an advantageous refinement of the present invention, it is also possible to mechanically blast the coated component before the heat treatment and after the PVD coating process. In this way, the coating can be compacted. It is also possible to mechanically blast the coated component, i.e., the blade 10 to be coated, before the PVD process. In this way the surfaces to be coated can be activated.

Thus in the sense of the present invention, a protective layer against oxidation and corrosion on components of a gas turbine is provided by producing a platinum-aluminum protective layer with the help of a PVD process using a platinum-aluminum target. As explained above, the target, i.e., coating material 18, may also contain other elements, e.g., and/or cobalt in addition to platinum and aluminum. In the sense of the present invention, it is provided for the first time that a platinum aluminum protective layer for a component be produced by a PVD process namely sputtering, i.e., cathode atomization. The platinum and aluminum are thus applied to the component to be coated in a joint process step. This makes it possible to shorten the production time for the protective layer.

As mentioned, the PVD coating is performed in a vacuum chamber, using a pressure of 10⁻⁶ mbar as the starting pressure for the PVD process. For the actual PVD coating, argon is then introduced into the vacuum chamber as a process gas.

The oxidation resistance of the component can be improved by the fact that the nickel-based alloy and/or the cobalt-based alloy of the component serving as the substrate contains yttrium and/or hafnium and/or silicon. Yttrium, hafnium and silicon promote the oxidation resistance of the component to be coated.

The inventive method is used especially on components for gas turbines, in particular on rotor blades, guide vanes, rotor blade segments, guide vane segments or for coating rotationally symmetrical components of a gas turbine, in particular an aircraft engine. The inventive protective layer is used preferably as a hot gas corrosion preventing layer on components of an aircraft engine.

1-13. (canceled)

14. A method for producing an oxidation and/or corrosion preventing layer for a component, especially a component of a gas turbine and especially a blade or blade segment, having at least one substrate surface and a substrate composition, by depositing a coating material on the component to be coated in a physical vapor deposition process, wherein a single target containing at least platinum and aluminum as the coating material is used and the coating material is deposited on the substrate surface simultaneously in one process step.

15. The method according to claim 14, wherein the substrate composition is comprised of a nickel-based alloy or a cobalt-based alloy.

16. The method according to claim 14, wherein the target additionally also contains nickel as the coating material.

17. The method according to claim 16, wherein the target additionally also contains cobalt as the coating material.

18. The method according. to claim 16, wherein the target additionally also contains yttrium and/or hafnium and/or silicon as the coating material.

19. The method according to claim 14, wherein cathode sputtering is used as the physical vapor deposition process.

20. The method according to claim 19, wherein the cathode sputtering is performed in a vacuum chamber under a protective gas atmosphere.

21. The method according to claim 20, wherein the protective gas atmosphere includes argon and/or krypton as a protective gas and/or a process gas.

22. The method according to claim 14, wherein the component is subjected to a heat treatment following the physical vapor deposition process.

23. The method according to claim 14, wherein the component is mechanically blasted following the physical vapor deposition process.

24. The method according to claim 14, wherein the component is mechanically blasted before the physical vapor deposition process.

25. The method according to claim 14, wherein the aluminum includes islands of the platinum integrated into the aluminum.

26. The method according to claim 14, wherein the target is formed by the aluminum and platinum in a form of an intermetallic phase.

27. The method according to claim 14, wherein a composition of the coating material is adapted to the component to be coated and also to the protective layer to be produced.

28. A method for producing a protective layer for a component, comprising the steps of:
depositing a coating material containing platinum and aluminum on the component by a physical vapor deposition process, wherein the platinum and aluminum are simultaneously deposited on the component by the physical vapor deposition process.

29. The method according to claim 28, wherein the physical vapor deposition process includes connecting the coating material to a voltage in a process chamber.

30. The method according to claim 29, wherein the physical vapor deposition process further includes the steps of:
accelerating gas ions of a process gas through a voltage field applied to the coating material;
depositing the gas ions on the coating material;
leveraging metal atoms out of the coating material by the deposited gas ions; and
depositing the leveraged metal atoms on the component.

31. An apparatus for producing a protective layer, comprising:
a process chamber adapted to receive a component to be coated with a coating material;
a cathode disposed within the process chamber, wherein the cathode includes the coating material and wherein the coating material contains platinum and aluminum;
a voltage source connected to the cathode; and
a process gas, wherein the process gas is acceleratable through a voltage field applied to the coating material.
